(19) United States
(12) Patent Application Publication
(10) Pub. No.: US 2025/0294922 A1
(43) Pub. Date: Sep. 18, 2025

(54) OPTOELECTRONIC DEVICE WITH SELECTABLE ANODE AND CATHODE REGIONS

(71) Applicant: INNOVATION SEMICONDUCTOR, INC., Rochester, NY (US)

(72) Inventor: Matthew T. HARTENSVELD, Wyckoff, NJ (US)

(21) Appl. No.: 19/078,840

(22) Filed: Mar. 13, 2025

Related U.S. Application Data
(60) Provisional application No. 63/565,158, filed on Mar. 14, 2024.

(51) Int. Cl. H10H 20/812; H01L 25/16; H10H 20/01; H10H 20/851; H10H 20/855

(52) U.S. Cl. CPC H10H 20/812; H01L 25/167; H10H 20/032; H10H 20/0361; H10H 20/0363; H10H 20/851; H10H 20/855

(57) ABSTRACT

A novel electrical isolation architecture that allows the ease of design for associated backplane circuitry based on NMOS transistors in optoelectronic device systems has been developed. Because of the very small dimensions of optoelectronic devices and their associated circuitry, performance limitations of PMOS transistors are more significant when used in backplanes of higher resolution optoelectronic device systems. Electrical isolation is provided through an electrically inactive p-type isolation region which enables electrical separation of individual cathodes for flexible device design for use with NMOS transistors. Efficiency is further improved by eliminating electrical crosstalk and parasitic currents between different optoelectronic devices. The novel electrical isolation of the cathodes additionally enables high resolution passive matrix arrays to be readily realized on a single wafer.

This application claims the benefit of U.S. Provisional Patent Application Ser. No. 63/565,158, filed Mar. 14, 2024, the entirety of which is incorporated herein by reference.

### FIELD

This technology relates to electrical isolation of optoelectronic elements within an optoelectronic device.

### BACKGROUND

Elements in optoelectronic devices, such as conventional light-emitting diodes (LEDs) or photodetectors, and the devices based on arrays of such elements, are composed of various active layers configured during semiconductor growth and processing. These active layers conventionally include an electron rich n-type region, a hole rich p-type region, and a multiple quantum well (MQW) region between the n-type and p-type regions. The MQW region is composed of multiple individual quantum wells which possess a smaller energy bandgap due to alloying, which are positioned between higher energy bandgap materials. The smaller energy bandgap quantum wells confine electrons and holes to facilitate recombination for light emission in the case of an LED, or light absorption by a detector. By way of example, for LEDs or photodiodes based on the III-N material system, Indium is typically alloyed with gallium nitride (GaN) in different amounts to shrink the bandgap of the quantum wells.

Optoelectronic devices comprising LEDs are regularly used in displays. In recent years, LEDs below 100 μm, known as micro-LEDs, have become advantageous for use in emerging display technologies due to enhanced brightness and reduced power requirements compared to existing LCD and OLED alternatives. LEDs and micro-LEDs utilized in display technologies or detector elements in optoelectronic sensors are typically connected to control circuitry to create a functional display or detector.

Conventionally, these elements are electrically connected to Si based controlling circuitry in what is typically referred to as a backplane control circuitry or electronics or simply backplane. Backplane is typically on a separate wafer, but in certain architectures can share a material system with the emitter or detector elements. Such architectures are termed monolithic when all active layers share a common material system. Connecting particularly micro-LED or detector optoelectronic elements with the backplane can take different forms such as, but not limited to, mass transfer printing of fabricated elements on a Si or glass backplane substrate, or direct substrate bonding of a preformed LED or detector array to a backplane. In addition to management of connectivity, the growing popularity of increasingly smaller devices, such as near-eye AR displays and micro-detectors, is imposing even more stringent performance requirements on the backplane.

Accordingly, as the market moves to higher resolutions and other performance requirements, particularly regarding micro-LED displays, cost and yield issues associated with mass transfer printing have become a material impediment, and device developers have increasingly turned to direct bonding of fabricated arrays onto a Si or alternative backplane. The primary advantage of direct bonding these substrates is the higher resolution and yield provided by avoiding limitations in placement accuracy associated with the mass transfer of individually fabricated micro-LEDs or detectors onto a separate substrate. Unfortunately, some approaches to higher resolution direct bonding involve materials and/or process steps that are not compatible with many commercial foundries, requiring dedicated, specialized foundry operations that add cost of manufacturing.

Additionally, longstanding optoelectronic device designs have been increasingly deficient in offering performance capacity optimal for functional LED displays or detector arrays that feature higher resolutions that can exceed thousands of pixels per inch and form factors that can be only several millimeters in length and width. Such displays benefit greatly from higher refresh rates that may require higher performance transistors in optoelectronic device control circuitry. These pressures will grow as resolution levels increase and smaller dimensions of both device elements and the associated backplane further challenge longstanding traditional optoelectronic device designs.

By way of reference, as used herein the term “anode” refers to an active p-type layer or region in an element, whether emitter or detector. Conversely, the term “cathode” refers to an active n-type region in an element, whether emitter or detector. In the growth of conventional LEDs and detectors, the p-type anode layer is grown after the n-type cathode due to growth differences of the structure, higher resistances, and different growth temperature requirements. The high resistances arise due to p-type dopants conventionally having increased ionization energy, such as in the case of Mg doping in GaN, negating the use as a common layer. After the lower temperature growth of the MQW region, the top layer must also be grown to avoid high temperatures damaging the MQW region. Having the p-GaN anode grown after the n-type cathode and MQW region provides the highest device performance, as a thin p-type layer grown after minimizes the negative impacts of both temperature and resistance. The device benefits from the use of the low resistive n-type layer serving as the continuous cathode that is common to each device. With this approach, optoelectronic devices, such as micro-LEDs, rely on connecting the device to associated control circuitry driven through the p-type anode region. This conventional design requires that the backplane circuitry is typically limited to the use of p-type metal oxide semiconductor (PMOS) transistors in display driving circuitry, such as a p-type configuration for an active-matrix circuit.

N-type metal oxide semiconductor (NMOS) transistors, while offering higher electrical performance, have not been effectively leveraged in micro-LED backplane circuitry. This configuration has not been fabricated based on the conventional device architectures as is the case in a typical optoelectronic device.

The conventional p-type configuration only requires a unique anode for each micro-LED, while the cathode is common due to the conventional LED structure. Thereby, PMOS transistors and p-type circuits are employed for driving high resolution micro-LEDs. Unfortunately, PMOS transistors have limitations, such as slower switching speeds, larger dimensions, increased power consumption, limited driving capabilities, increased design complexity, and reduced noise margin, compared to NMOS transistor configured in n-type active matrix or other circuits.

Structuring a unique cathode for each element of a higher resolution optoelectronic device, such as a micro-LED or detector element, is exceedingly difficult to achieve with a conventional structure. The cathode is conventionally an n-type region which is grown on a substrate before the rest of the optoelectronic device structure, due to the later anode growth being limited to lower temperatures. The cathode of such devices is often designed to be a few microns thick for low resistance and improved crystal quality. The cathode also commonly shares conductivity with any buffer regions which may be below it. As such, methods of etching through the p-type anode, MQW region, n-type cathode, and any buffer regions down to the substrate to provide complete electrically isolation of the cathode for each element is commercially untenable due to processing drawbacks, large step-height differences, and lower array resolution.

A common cathode design also negatively impacts other forms of optoelectronic arrays, known as passive matrix arrays, which do not rely on direct circuitry control for each sub-pixel. Passive matrix arrays are commonly used in applications requiring small areas. A passive matrix utilizes only external inputs to the optoelectronic elements through the rows/columns, making for a simplified approach. A passive matrix is an array with each anode tied to a row/column and each cathode tied to a column/row, respectively. Due to the n-type region in conventional LED or detector growth structures being common, all the cathodes are tied together with the inability to be formed into separate column/rows. This has largely negated the use of high-resolution passive matrix arrays for micro-LEDs or micro-detectors.

Non-LED optoelectronic devices, such as detectors, have more flexibility in that often a mixed configuration both NMOS and PMOS transistors are utilized. Choices of detector circuit configurations though are still limited by a common cathode configuration, where often the best high-performance designs are unable to be effectively leveraged. The common cathode also places constraints on the adjustability of the detector sensitivity in arrays.

Accordingly, as discussed above the lack of uniquely addressable cathodes in optoelectronic devices, such as micro-LEDs or detectors, is a key impediment to realizing many high resolution and high performance devices, limiting options, and creating some level of sacrifice which is non-ideal for large scale commercial products.

### SUMMARY

Examples of this technology relate to optoelectronic devices that include multiple optoelectronic emitter or detector elements that have unique flexibility in connecting to external control circuitry. Such devices include, in addition to a cathode region, an anode region, an MQW region, and an electrically inactive p-type isolation region common to all elements. The use of the electrically inactive p-type isolation region allows each element in a device, whether through the cathode and/or anode, to be independently connected to either the associated power source circuitry or the downstream backplane circuitry.

In examples of this technology, the term ‘electrically inactive p-type isolation region’ refers to a region within the optoelectronic device structure that is doped to have an excess of holes, rendering the region p-type. This region is functionally electrically inactive in the operation of elements in an optoelectronic device and is positioned beneath at least one cathode in an element, relative to the orthogonal of the substrate. The region acts as an electrically insulating isolation region that physically and electrically separates the cathode of each element in an optoelectronic device from others, in contrast to the conventional configuration where a common cathode is shared by all such elements.

In accordance with other examples of this technology, optoelectronic devices are configured to provide systems and methods to engineer unique cathode and anode regions and connections for each emitter or detector element. In one example, an electrically inactive p-type electric isolation region, a cathode, an MQW region, and an anode are formed on a common substrate, with the isolation region providing physical and electrical separation of each element in a device. The layers of the structure are created such that the cathode, the MQW region, and anode can be unique down to each emitter or detector on a common p-type electrical isolation region. The emitter or detector elements can be crafted into device arrays functioning as, for example, displays or detectors that can optionally be connected electrically to a controlling transistor backplane using a variety of techniques.

An optoelectronic device as defined herein comprises a plurality of optoelectronic elements where each of the elements are physically and electrically spaced from each other in the device and are located on an electrically inactive isolation region common to all the elements. The active layers comprise, in adjacent order above the isolation region: a cathode region; an MQW region located over a portion of the cathode region; and an anode region located over the MQW region.

A method for making an optoelectronic device comprising a plurality of optoelectronic elements where each of the elements is spaced from each other in the device includes providing an electrically inactive isolation region common to all the elements in a device. An n-type (cathode) region is formed over the electrically inactive isolation region. A separate MQW region for each of the elements is formed over a portion of the cathode region to allow the cathode region to be easily connected to external control circuitry. A separate p-type (anode) region is formed over each of the MQW regions for each of the elements. Alternatively, a continuous n-type (cathode) region, a MQW region, and a p-type (anode) region are first grown over the electrically inactive isolation region. Conventional semiconductor fabrication processes can be employed where subsequent selective etches are performed in order to form isolated p-type (anode) and MQW regions on separated n-type (cathode) regions.

This technology provides several advantages including electrical efficiency, flexibility to connect to backplane circuitry either through the cathode or, alternatively if preferred, through the anode, better fault tolerance, better thermal management, as well as enabling novel monolithic passive-matrix devices. These benefits can be effectively utilized in a number of different applications, such as displays, commercial lighting, communications, detectors, and more. In particular, examples of this technology provide an isolation approach to enable the utilization of higher performing NMOS circuitry, along with enabling high resolution monolithic passive matrix arrays. Monolithic is defined herein as the same InGaN/GaN, III-N, or other material system used within the same wafer.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1(a) is a cross-sectional diagram of an example of a prior art optoelectronic device growth stack;

FIG. 1(b) is a cross-sectional diagram of an example structure of an optoelectronic growth stack including an electrically inactive p-type isolation region;

FIG. 2 is a cross-sectional image of an example of a prior art optoelectronic device array based on a conventional structure with a common cathode; and

FIG. 3 is a cross-sectional image of an example optoelectronic device array which incorporates an electrically inactive p-type isolation region.

### DETAILED DESCRIPTION

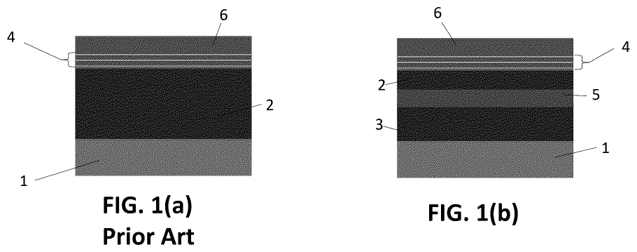

An example of a conventional growth stack is illustrated in FIG. 1(a). As used for examples herein, the term “active” is used to indicate that an n-type or p-type region is electrically engaged in the operation of an optoelectronic element or device.

As used herein the term cathode refers to the active n-type region of an optoelectronic element and the term anode refers to the active p-type region. These may be connected in a number of alternate configurations based on desired functionality. Alternative configurations are described in the examples.

In FIG. 1(a), the growth stack includes a cathode 2, an anode 6, and a multiple quantum well (MQW) region 4, all on a common substrate 1. The growth stack can comprise materials such as AlGaN, GaN, InGaN, AlInGaP, by way of example. The common substrate 1 can be, but is not limited to, choices of Silicon, GaN, GaAs, or Sapphire. The cathode 2 often comprises one or more layers, such as buffer layers, which may have different levels of effective n-type conductivity.

Referring more specifically to FIG. 1 (a), the cathode 2 is conventionally shared as in the fabrication of optoelectronic devices, such as detectors or LEDs. The use of a common cathode 2, shared by all elements is conventional due to the challenges associated with manufacturing of isolation trenches which often necessitate comparatively deep etches through the material down to the substrate 1 to electrically and mechanically isolate individual devices.

The MQW region 4 is formed in contact with the cathode 2. The MQW region 4 comprises multiple individual quantum wells which have differing material composition and smaller energy bands compared to the surrounding material. Common MQWs may comprise InGaN surrounded by GaN barriers, by way of example. Light can be absorbed or emitted from the MQW region 4 depending on how the device is structured and utilized, for applications, such as that of a photodetector or an LED, respectively.

The anode 6 is in contact with the MQW region 4. The anode 6 may include multiple different types of materials and doping concentrations, such as an electron blocking layer by way of example. Conventionally, a comparatively shallow etching process is done to selectively etch through portions of the anode 6 and the MQW region 4 to form individual optoelectronic devices with a common cathode 2. The anode 6 is typically designed thinner due to increased resistivity over the cathode 2, as well as to minimize thermal damage to the MQW region 4. Etching through the anode 6 and MQW region 4 provides optoelectronic devices with unique anodes.

In contrast, the exemplary novel structure shown in FIG. 1(b) provides an additional, electrically inactive p-type isolation region 5 common across all optoelectronic elements in a device. The electrically inactive p-type isolation region 5 is electrically inactive in the operation of elements in a device, having only a small leakage current several orders in magnitude less than the driving current through the optoelectronic device. It may comprise GaN, AlGaN, InGaN, or AlInGaP, by way of example.

The substrate 1 may comprise Silicon, GaN, GaAs, or Sapphire by way of example. A buffer base region 3 can be formed on the substrate 1 which may comprise one or more layers which may be doped n-type, p-type, or unintentionally doped. The base region 3 is included as needed to serve the purpose of minimizing defects and better matching the lattice constant for the formation of the device regions. The base region 3 is not active electrically in the functionality of the optoclectronic elements or devices.

The electrically inactive p-type isolation region 5 can be formed on the base region 3, or on the substrate 1 if the lattice constants of both the substrate 1 and the electrically inactive p-type isolation region 5 are acceptably close and a base region 3 is not present. The electrically inactive p-type isolation region 5 serves as an electrical isolation region which enables the formation of unique and independent anodes 6 and cathodes 2 that can be controlled independently in an optoelectronic device. The independent anodes 6 and cathodes 2 enable advantageous circuitry to be integrated with each optoelectronic element as well as the realization of high-resolution passive-matrixes. A cathode 2 is formed adjacent to the electrically inactive p-type isolation region 5. The cathode 2 can comprise n-type GaN, although other types and/or numbers of layers or materials may be used.

The MQW region 4 is formed in contact with the cathode region 2. The MQW region 4 comprises multiple individual quantum wells which have differing material composition and smaller energy band compared to the surrounding material. MQW region 4 may comprise InGaN surrounded by GaN barriers, by way of example. Light can be absorbed or emitted from the MQW region 4 depending on how the device is structured and utilized, for applications such as that of a photodetector or an LED, respectively.

The anode 6 is in contact with the MQW region 4. The anode 6 may comprise multiple different types of materials and doping concentrations, by way of example the inclusion of an electron blocking layer.

The electrically inactive p-type isolation region 5 provides electrical isolation through the formation of a depletion region in conjunction with the cathode 2. When the n-type cathode region 2 is formed on the electrically inactive p-type isolation region 5, electrons from the n-type cathode region 2 are neutralized by the holes from the electrically inactive p-type isolation region 5 creating a depletion region. This depletion region is a region with ionized donors and acceptors which have donated or received an electron, respectively, and form positive and negative charges at the interfaces of the two separately doped materials. The depletion region creates an electric field which opposes the continued flow of electrons and holes between the n-type cathode region 2 and electrically inactive p-type isolation region 5. The depletion region thereby electrically isolates the n-type cathode region 2 from the electrically inactive p-type isolation region 5 and subsequently any base region 3, creating the electrical inactivity of p-type region 5 and electrical isolation between cathode 2 elements. Use of the electrically inactive p-type isolation region 5 can enable unique and independent cathode regions 2 to be formed in each optoelectronic element in a device, where selective patterning can be done to pattern the cathodes 2 such that shallow individual islands within elements of the cathode region 2, MQW region 4, and anode 6 are electrically separated from each other on the electrically inactive p-type isolation region 5. The depletion region formed between each n-type cathode 2 and p-type isolation region 5 prevents flow of current between neighboring elements in a device.

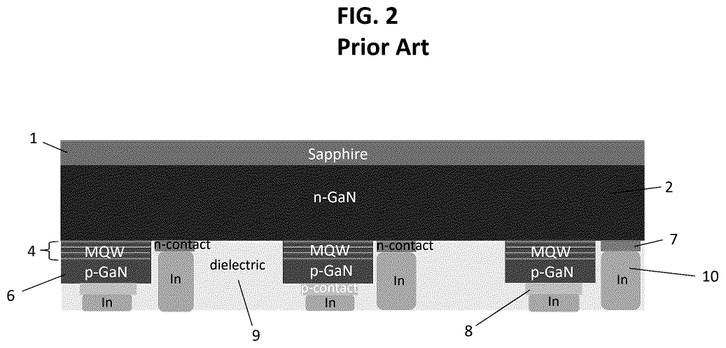

Referring to FIG. 2, a cross sectional view of an example of a prior art optoelectronic system based on the conventional structure of FIG. 1(a) with a common cathode 2 design. To form the device array unique anode 6 and MQW regions 4 are etched or selectively grown to form photonic elements on a common cathode 2. The cathode 2 can be composed of multiple layers, which are intentionally or unintentionally doped n-type, and act as both the common cathode 2 for electrical operator of each element and as the mechanical supporting layer grown from the substrate. To provide mechanical support, electrical performance, and reduced defect density, the cathode 2 is often grown several microns thick. By way of example the cathode 2 can be one to eight microns thick, making a comparatively deep etch necessary in order to form independent cathodes. Once fabricated these optoelectronic elements in a device array are limited in that the driving circuitry has to be integrated through each anode 6, due to the nature of the common cathode 2 for the devices.

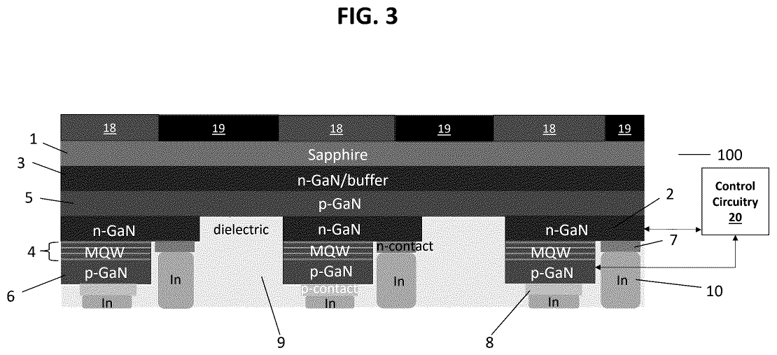

Referring to FIG. 3, a cross sectional view of an example optoelectronic system 100 in accordance with examples of this technology is illustrated. Exemplary optoelectronic system 100 incorporates an electrically inactive p-type isolation region 5 for electrical isolation of the cathodes 2, which in this configuration may be several hundred nanometers thick and doped above 1E17/cm³, by way of example.

In this example the base structure of FIG. 1(b) is leveraged. The optoelectronic system follows a conventional fabrication approach where the anode 6 and MQW region 4 are selectively patterned to form each unique photonic element such as an LED or detector. An additional selective patterning step is performed such that the cathode 2 in each element is physically and electrically separated from other elements, thus unique in this respect, as are each element's anode 6 and MQW region 4. In this exemplary device the cathode 2 thickness is separated from any buffer layer 3 which by necessity in this example may be one to seven microns thick. The cathode 2 can be engineered to be less than 500 nm thick, providing low electric resistance, while not excessively thick as to not be easily patterned and etched for each element. Additional metal contacts can be formed such as p-type contacts 8 on the p-type anode 6 and n-type contacts 7 on the n-type cathode 2. Common metal choices for the p-type contacts 8 may include Ni and Au, while the n-type contacts 7 may be of Ti, Al, Ni, Au, by way of example. A dielectric spacer 9 may be formed and patterned on the surface for purposes of further electrical isolation and protection. The substrate or substrate region 1, cathode 2, patterned MQW region 4, patterned anode 6, n-type contact 7, p-type contacts 8, and dielectric spacer 9 can form an optoelectronic element, though in some cases the substrate 1 can be removed. Accordingly, as described in this example a color converter 18 also is formed over a portion of the substrate 1 and buffer layer 3 in alignment with the MQW region 4 for each optoelectronic element in a device, although other configurations can be used, such as between substrate 1 and buffer layer 3 and in alignment with the MQW region 4 for each optoelectronic element in a device by way of example only. Additionally, in this example a light block matrix element 19 is located between each of the color converters 18 for each optoelectronic element in a device.

To present an array of optoelectronic elements in a complete device, additional conventional control circuitry, widely disclosed, can be utilized with each element. The utilization of this additional control circuitry 20 coupled to the cathode 2 or anode 6 for each of the optoelectronic elements may be provided through the use of bonding a silicon CMOS wafer to a fabricated array of optoelectronic elements. By way of example if the optoelectronic elements are LEDs, the more advantageous NMOS driving circuitry can now be used to control the current through each LED. By way of another example, the control circuitry 20 may be PMOS or a combination of NMOS and PMOS control circuitry coupled through the p-type anode 6 and n-type cathode region 2 of each of the elements.

The novel use of the electrically inactive p-type isolation region 5 which provides isolated cathodes 2, can additionally be readily utilized to form high resolution passive-matrix arrays. Passive-matrix arrays, widely disclosed, do not require control circuitry integrated with each optoelectronic element in an array, and instead are addressed through the rows and columns of the array. A passive matrix array has the benefit of a comparatively simple design, though with limitations on overall size. High resolution passive-matrix optoelectronic arrays are enabled due to the now shallow etches required to form the cathodes 2. The cathodes 2 in FIG. 2 can extend orthogonally into the plane to form columns with multiple optoelectronic elements in parallel, while the anodes 6 can be laterally linked, forming parallel rows. The rows and columns formed for a complete optoelectronic passive-matrix device can be electrically addressed as widely covered in prior art, whether the optoelectronic device is a detector or emitter. Such passive matrix arrays may or may not make use of another substrate to connect the row/column ends to for additional multiplexing and other driving functionality.

Accordingly, as illustrated and described by way of the examples herein, devices based on this exemplary technology provide greater device speeds, smaller dimensions, reduced power consumption, reduced complexity, and greater fault tolerance, which may be effectively utilized in a number of different optoelectronic device applications, such as displays, detectors, communications, and more. In particular, examples of this technology enable NMOS transistor sub-pixel driving for high resolution LED displays, and high resolution monolithic passive matrix arrays. Examples of this technology are able to provide numerous performance benefits without the difficulties associated with deep selective isolation patterning.

Having thus described the basic concept of the technology and invention, the foregoing detailed disclosure is intended to be presented by way of example only and is not limiting. Various other examples alterations, improvements, and modifications will occur and are intended to those skilled in the art, though not expressly stated herein. These alterations, improvements, and modifications are intended to be suggested hereby, and are within the spirit and scope of the technology. Additionally, the recited order of processing elements or sequences, or the use of numbers, letters, or other designations therefore, is not intended to limit the scope of the present invention.

What is claimed is:

1. An optoelectronic device comprising a plurality of optoelectronic elements, each of the elements physically and electrically spaced from each other in the device and further comprises, in adjacent order from an electrically inactive isolation region common to all of the elements:
an n-type cathode region;
an MQW region located over a portion of the n-type cathode region; and
a p-type anode region located over the MQW region.

2. The optoelectronic device as set forth in claim 1, further comprising control circuitry coupled to one of either the p-type anode region or the n-type cathode region of each of the elements.

3. The optoelectronic device as set forth in claim 2 wherein the control circuitry comprises NMOS control circuitry coupled through the n-type cathode region of each of the elements.

4. The optoelectronic device as set forth in claim 1, wherein the electrically inactive isolation region comprises an electrically inactive p-type isolation region.

5. The optoelectronic device as set forth in claim 1, further comprising at least one of a buffer base region or a substrate region over a surface of the electrically inactive isolation region located opposite from the n-type cathode region and p-type anode region of each of the elements.

6. The optoelectronic device as set forth in claim 1 wherein the optoelectronic elements each comprise an LED.

7. The optoelectronic device as set forth in claim 6 wherein each of the optoelectronic elements further comprises:
a color converter over a portion of the electrically inactive isolation region in alignment with the MQW region; and
a light block matrix between each of the color converters for the optoelectronic elements.

8. The optoelectronic device as set forth in claim 1 wherein the optoelectronic elements each comprise a light absorbing detector.

9. A method for making an optoelectronic device comprising a plurality of optoelectronic elements where each of the elements is physically and electrically spaced from each other in the device and, in adjacent order above and from an electrically inactive isolation region common to all of the elements, each comprises:
an n-type cathode region;
an MQW region located over a portion of the n-type cathode region; and
a p-type anode region located over the MQW region,
the method comprising:
providing the electrically inactive isolation region common to all of the elements;
forming the n-type cathode region over the electrically inactive isolation region;
forming a separate one of the MQW region for each of the elements over the n-type cathode region; and
forming a separate one of the p-type anode region over each of the MQW regions for each of the elements.

10. The method as set forth in claim 9, further comprising:
separately coupling control circuitry to one of either the p-type anode region or the n-type cathode region of each of the elements.

11. The method as set forth in claim 10 wherein the control circuitry comprises NMOS control circuitry coupled to the n-type cathode region.

12. The method as set forth in claim 9, wherein the electrically inactive isolation region comprises an electrically inactive p-type isolation region.

13. The method as set forth in claim 9, further comprises:
forming at least one of a buffer base region or a substrate region over a surface of the electrically inactive isolation region opposite from the elements.

14. The method as set forth in claim 9 wherein the optoelectronic elements each comprise an LED.

15. The method as set forth in claim 14 further comprises:
forming a color converter over a portion of the electrically inactive isolation region in alignment with the MQW region for each of the elements; and
forming a light block matrix between each of the color converters for the elements.

16. The method as set forth in claim 9 wherein the optoelectronic elements each comprise a light absorbing detector.
